(19) United States
(12) Patent Application Publication
(10) Pub. No.: US 2026/0047366 A1
(43) Pub. Date: Feb. 12, 2026

(54) OXIDE LAYER AND PROCESS OF FORMING THE SAME AND SEMICONDUCTOR DEVICE AND METHOD OF MANUFACTURING THE SAME

(71) Applicants: SAMSUNG ELECTRONICS CO., LTD., Suwon-si (KR); Industry-University Cooperation Foundation Hanyang University, Ansan-si (KR)

(72) Inventors: Yongsuk CHO, Suwon-si (KR); Woo-Hee KIM, Ansan-si (KR); Hyekyung KIM, Ansan-si (KR); Seung-Yeon KWAK, Suwon-si (KR); Hwea Yoon KIM, Suwon-si (KR); Seungyeol BAEK, Suwon-si (KR); Kijung JUNG, Suwon-si (KR); Jong Won CHOI, Suwon-si (KR); Dmitry KRAVCHUK, Suwon-si (KR); Seo-Hyun LEE, Ansan-si (KR)

(21) Appl. No.: 19/246,021

(22) Filed: Jun. 23, 2025

(30) Foreign Application Priority Data
Aug. 6, 2024 (KR) 10-2024-0104493

(51) Int. Cl. H01L 21/02; C23C 16/44; C23C 16/455; C23C 16/56; H10B 12/00

(52) U.S. Cl. CPC H01L 21/02164; C23C 16/4408; C23C 16/45534; C23C 16/56; H01L 21/02211; H01L 21/0228; H01L 21/02337; H10B 12/033; H10B 12/053; H10B 12/315

(57) ABSTRACT

A process of forming an oxide layer, the oxide layer, a semiconductor device, and a method for manufacturing a semiconductor device. The process of forming the oxide layer including conducting atomic layer deposition at a temperature of less than about 400° C., wherein the atomic layer deposition includes: supplying a metal or semi-metal precursor and a first reaction catalyst to a substrate positioned in a chamber for atomic layer deposition to adsorb the metal or the semi-metal precursor on a surface of the substrate; and supplying a reactant and a second reaction catalyst to the substrate on which the metal or semi-metal precursor is adsorbed to form the oxide layer, wherein the first reaction catalyst and the second reaction catalyst comprise primary or secondary amine, respectively.

### CROSS-REFERENCE TO RELATED APPLICATION

This application claims priority to Korean Patent Application No. 10-2024-0104493 filed in the Korean Intellectual Property Office on Aug. 6, 2024, and all the benefits accruing therefrom under 35 U.S.C. § 119, the entire content of which is incorporated herein by reference.

### BACKGROUND

### 1. Field

An oxide layer, a process of making the same, a semiconductor device, and a method of manufacturing the same.

### 2. Description of the Related Art

As the demand for various digital devices continues to increase, the development and demand for integrated circuit devices has also increased. Recent development of integrated circuit devices has focused on reducing the component dimensions of unit cells, and accordingly, methods suitable for process scaling are required and of interest.

### SUMMARY

An embodiment provides a process of forming an oxide layer that may be formed at a relatively low temperature and exhibit comparable thin film performance to similar layers prepared at significantly higher temperatures.

Another embodiment provides an oxide layer formed at relatively low temperatures and exhibits good film performance.

Another embodiment provides a method of manufacturing a semiconductor device including the oxide layer.

Another embodiment provides a semiconductor device including the oxide layer.

According to an embodiment, a process of forming an oxide layer includes conducting atomic layer deposition at a temperature of less than about 400° C., wherein the atomic layer deposition includes:
supplying a metal or semi-metal precursor and a first reaction catalyst to a substrate positioned in a chamber for atomic layer deposition to adsorb the metal or semi-metal precursor to a surface of the substrate; and
supplying a reactant and a second reaction catalyst to the substrate on which the metal or semi-metal precursor is adsorbed to form the oxide layer,
wherein the first reaction catalyst and the second reaction catalyst include primary or secondary amine, respectively.

At least one of the first reaction catalyst or the second reaction catalyst may include a C1 to C5 monoalkylamine, a C1 to C5 dialkylamine, or a combination thereof.

At least one of the first reaction catalyst or the second reaction catalyst may include ethylamine.

The metal or semi-metal precursor may include a halosilane, a halodisilane, an alkoxysilane, an alkoxydisilane, an organosilane, an organodisilane, a metal halide, a metal alkoxide, an organometallic precursor, or a combination thereof, and the reactant may include H₂O, H₂O₂, O₂, O₃, or a combination thereof.

The process may further include supplying a first purge gas following the adsorbing of the metal or semi-metal precursor to the surface of the substrate, and before the supplying the reactant and the second reaction catalyst; and supplying a second purge gas after the supplying the reactant and the second reaction catalyst to the substrate.

The atomic layer deposition may be conducted at room temperature to less than or equal to about 150° C.

The process may further include conducting an ozone treatment after conducting the atomic layer deposition. For example, the process may further comprise conducting an ozone treatment of an intermediate oxide layer following two or more atomic deposition cycles, wherein one atomic deposition cycle includes the supplying the metal or semi-metal precursor and the first reaction catalyst, and the supplying the reactant and the second reaction catalyst.

The conducting of the atomic layer deposition may be performed 1 to 300 cycles to form the oxide layer, and the process may further include conducting an ozone treatment of the oxide layer. For example, where one atomic layer deposition cycle includes the supplying the metal or semi-metal precursor and the first reaction catalyst, and the supplying the reactant and the second reaction catalyst,
a number of 2 to 300 atomic layer deposition cycles is conducted to form an intermediate oxide layer, and
conducting an ozone treatment on the intermediate oxide layer following the number of atomic layer deposition cycles, wherein the ozone treatment is conducted two or more times over a total number of atomic layer deposition cycles.

The process may further include annealing the oxide layer.

A carbon content in the oxide layer may be less than about 2.0 at %.

The oxide layer may be a silicon oxide layer.

According to another embodiment, an oxide layer formed in accordance with an embodiment of a process above and having a carbon content of less than about 2.0 atomic percent (at %).

The oxide layer may be a silicon oxide layer and an atomic ratio of oxygen to silicon in the silicon oxide layer may be about 1.45:1 to about 2.00:1.

According to another embodiment, a semiconductor device includes a semiconductor substrate, a transistor integrated in or positioned on the semiconductor substrate, and a capacitor electrically connected to the transistor, wherein at least one of the transistor or the capacitor comprises the oxide layer.

According to another embodiment, a method of manufacturing a semiconductor device includes forming a transistor integrated in or positioned on a semiconductor substrate, and forming a capacitor electrically connected to the transistor, wherein at least one of forming the transistor or forming the capacitor includes forming an oxide layer, and the forming of the oxide layer is performed by the process.

A carbon content in the oxide layer may be less than about 2.0 at %.

The oxide layer in the semiconductor device may be a silicon oxide layer, and an atomic ratio of oxygen to silicon in the silicon oxide layer may be about 1.45:1 to about 2.00:1.

The forming of the capacitor may include forming a first electrode, forming the oxide layer by the aforementioned process, and forming a second electrode.

The forming of the transistor may include forming a trench in the semiconductor substrate, forming the oxide layer in the trench by the process, and forming a gate conductor on the oxide layer.

The oxide layer may be formed as a continuous thin film with a substantially uniform thickness along an inner wall of the trench of the semiconductor substrate.

### BRIEF DESCRIPTION OF THE DRAWINGS

FIG. 1 is a schematic representation showing an example of an atomic layer deposition apparatus for forming an oxide layer according to an embodiment,

FIG. 2 is a schematic representation showing the chemisorption mechanism of a precursor according to an example in atomic layer deposition,

FIG. 3 is a schematic representation showing the adsorption mechanism of a reactant according to an example in atomic layer deposition,

FIG. 4 is a graph showing one cycle according to an example in atomic layer deposition,

FIG. 5 is a graph showing an example of the sequence of the atomic layer deposition process and ozone treatment according to an example in atomic layer deposition,

FIG. 6 is a cross-sectional representation showing an example of a semiconductor device according to an embodiment, and

FIG. 7 is a cross-sectional representation showing another example of a semiconductor device according to an embodiment.

### DETAILED DESCRIPTION

Hereinafter, the embodiments will be described in detail so that those of ordinary skill in the art may easily implement them. However, the actually applied structure may be implemented in several different forms and is not limited to the embodiments described herein.

The terminology used herein is used to describe embodiments only, and is not intended to limit the present disclosure. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

In the drawings, the thickness of layers, films, panels, regions, etc., are exaggerated for clarity and like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present. The drawings and description are to be regarded as illustrative in nature and not restrictive. Like reference numerals designate like elements throughout the specification. Hereinafter, the terms “on” or “upper” may include not only things that are directly above, below, left, or right in contact, but also things that are non-contacting above, below, left, or right. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “combination thereof” refers to a mixture, a stacked structure, a composite, an alloy, or a blend of constituents.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, or ±1% of the indicated value or within a standard deviation.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Due to scaling of a process, a thickness of a channel region such as silicon, may become thinner, and in this case, the channel region may become more readily oxidized by diffusion of oxygen from an oxide layer during the oxide layer formation process. As a result, the relatively thin oxidized regions may cause a short circuit between adjacent channel regions. Moreover, because oxygen diffusion may be greater at higher process temperatures in forming the oxide, it may be of interest to form an oxide layer at relatively lower process temperatures. The following describes a process of forming an oxide layer according to an embodiment.

An oxide layer according to an embodiment may include a metal oxide, a semi-metal oxide, or a combination thereof, and may be formed by atomic layer deposition (ALD). The atomic layer deposition may provide a layer, e.g., a monolayer film, with a thickness of several angstroms to tens of nanometers per ALD cycle by utilizing chemisorption and self-saturated or a hydrolysis reaction. Of course, the ALD cycle may be repeated multiple times to form an oxide layer with a desired thickness. The atomic layer deposition may be performed by placing a substrate on which a layer, e.g., an oxide layer, is to be deposited in an atomic layer deposition chamber and supplying metal or semi-metal precursors and other reactants or catalysts in a gas phase into the chamber.

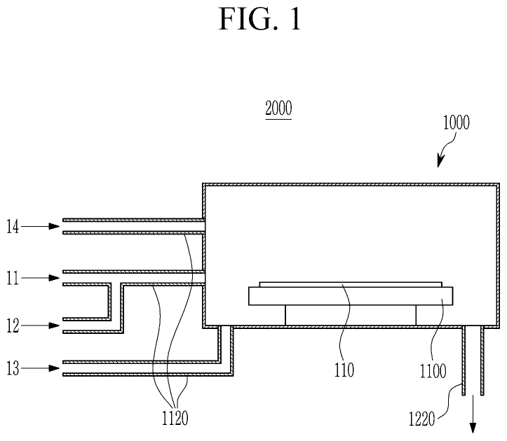

FIG. 1 is a schematic representation of an atomic layer deposition device for forming an oxide layer according to an embodiment. An atomic layer deposition apparatus 2000 includes an atomic layer deposition chamber 1000 including a substrate support 1100 on which a substrate 110 is to be positioned, an inlet system 1120 configured to supply a metal or semi-metal precursor 11 (hereinafter referred to as “precursor”), a reaction catalyst 12, a reactant 13, and a purge gas 14, and an outlet 1220 configured to discharge one or more of reaction by-products, non-adsorbed precursor, non-reactive catalyst, non-reactive reactant, and purge gas. The atomic layer deposition apparatus 2000 may additionally include a pressure control pump (not shown), which may maintain the atomic layer deposition chamber 1000 at a predetermined vacuum or low pressure. The atomic layer deposition chamber 1000 may be maintained at a pressure of, for example, about 10 Torr or less, and may be maintained at, for example, about 10⁻³ Torr to about 10 Torr.

The atomic layer deposition may be conducted at a relatively low temperature, for example, less than about 400° C. The temperature may be an internal temperature of the atomic layer deposition chamber 1000 and/or the temperature of the substrate 110 (or substrate support 1100) on which the oxide layer is deposited, and may be maintained at or near the deposition temperature during the atomic layer deposition process. The atomic layer deposition temperature may be, within the above range, from room temperature (about 25° C.) to about 380° C., from room temperature to about 350° C., from room temperature to about 300° C., from room temperature to about 250° C., from room temperature to about 200° C., from room temperature to about 150° C., from room temperature to about 100° C., from about 50 to about 380° C., from about 50° C. to about 350° C., from about 50° C. to about 300° C., from about 50° C. to about 250° C., from about 50° C. to about 200° C., from about 50° C. to about 150° C., or from about 50 to ° C. about 100° C.

The process for the atomic layer deposition may include supplying a precursor 11 and a reaction catalyst 12 to a substrate 110, and supplying a reactant 13 and a reaction catalyst 12.

A substrate 110 is placed on a substrate support 1100 of an atomic layer deposition chamber 1000, and a precursor 11 and a reaction catalyst 12 are supplied (added to the chamber at or near the deposition temperature. The precursor 11 and the reaction catalyst 12 may be, for example, supplied sequentially in any order or simultaneously.

The substrate 110 may be, for example, a silicon substrate, a substrate covered with a silicon oxide layer, or a substrate covered with another layer. For example, hydroxyl groups may be adsorbed on a surface of a silicon substrate or silicon oxide layer to form Si—OH bonds. The Si—OH bonds may be obtained by surface treatment of a silicon substrate or a silicon oxide layer, for example, by supplying an SC-1 solution (a mixed solution of NH₄OH, H₂O₂, and water) and performing a heat treatment.

The precursor 11 may provide a metal or a semi-metal to the substrate surface from which a metal or semi-metal oxide is to be formed. The precursor 11 may include a halosilane, a halodisilane, an alkoxysilane, an alkoxydisilane, an organosilane, an organodisilane, a metal halide, a metal alkoxide, an organometallic precursor, or a combination thereof, but is not limited thereto. The precursor metal may include Al, Mo, Ni, Ti, Ta, an alloy thereof, or a combination thereof, but is not limited thereto. The halosilane or halodisilane may be, for example, SiCl₄, Si₂Cl₆, or a combination thereof.

The reaction catalyst 12 may include a primary or secondary amine catalyst. The primary amine catalyst may be represented by R¹NH₂ and the secondary amine catalyst may be represented by R²R³NH, where R¹ to R³ may each independently be a C1 to C20 alkyl group. For example, R¹ to R³ may be a short chain alkyl group, for example a C1 to C5 alkyl group. For example, the primary amine catalyst may be a C1 to C5 monoalkylamine catalyst and the secondary amine catalyst may be a C1 to C5 dialkylamine catalyst. For example, the primary amine catalyst may be methylamine, ethylamine, propylamine, and/or butylamine, the secondary amine catalyst may be dimethylamine, diethylamine, methylethylamine, dipropylamine, methylpropylamine, ethylpropylamine, dibutylamine, methylbutylamine, butylethylamine, and/or butylpropylamine, but are not limited thereto. For example, the reaction catalyst 12 may include ethylamine.

The primary or secondary amine catalyst may increase the reactivity of the precursor 11 and the hydroxyl group (—OH), or the adsorption of the precursor 11, to the substrate 110 at a relatively low temperature. For example, the precursor 11 such as SiCl₄ or Si₂Cl₆ has high chemical stability, so that chemisorption using the hydroxyl group (—OH) on the substrate 110 as an adsorption site at the relatively low temperature described above may not be relatively facile or the reaction (or chemisorption) rate may be relatively slow. The primary or secondary amine catalyst may facilitate absorption of precursor 11 onto substrate 110 at a higher rate by activating hydroxyl groups (—OH) on the substrate at the relatively low temperature described above to induce a reaction with the precursor 11. The precursor 11 adsorbed on the substrate 110 may be formed into a monolayer by a self-saturated reaction.

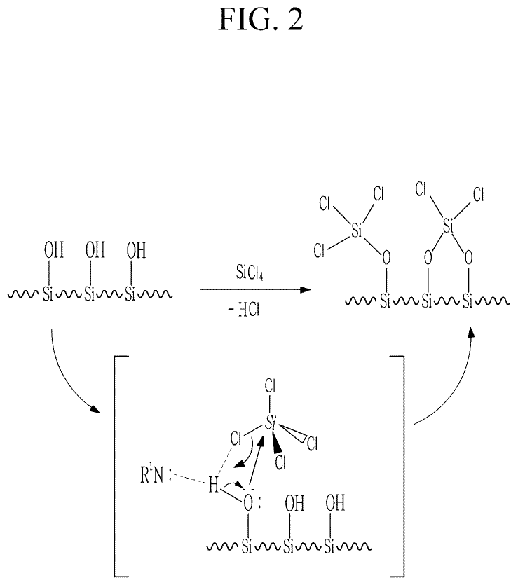

FIG. 2 is a schematic representation showing a proposed chemisorption mechanism of a precursor to the substrate in the atomic layer deposition. Referring to FIG. 2, when SiCl₄ is supplied as the precursor 11 and a primary amine (R¹NH₂) catalyst is supplied as the reaction catalyst 12 to a substrate 110 having a Si—OH surface, the primary amine catalyst may activate the hydroxyl group (—OH) of the substrate to increase the reactivity between the hydroxyl group (—OH) and the reactive group (—Cl) of the precursor 11, thereby rapidly adsorbing the precursor 11 onto the substrate surface to form a Si—O—Si bond.

The primary or secondary amine catalyst may further increase the reaction rate between the precursor 11 and the surface of the substrate 110 than tertiary amine catalysts or nitrogen-containing ring catalysts such as pyridine and pyrimidine, and at the same time, may be more readily decomposed after the reaction, effectively reducing or eliminating catalyst residues (e.g., ammonium salts and/or carbon impurities). Accordingly, the precursor 11 may be effectively adsorbed onto the surface of the substrate 110 while reducing or preventing chemical and electrical deterioration of the thin film due to catalyst residue.

Subsequently, a purge gas 14 may be supplied to the chamber 1000 to perform a first purging. The purge gas 14 may include, for example, N₂, Ne, Ar, He, or a mixed gas thereof, and may be supplied at a flow rate of, for example, about 10 standard cubic centimeters per minute (sccm) to about 2000 sccm. The first purging may remove impurities in the atomic layer deposition chamber 1000 by discharging unreacted substances and/or reaction byproducts of the aforementioned precursor through the outlet 1220.

Next, a reactant 13 and a reaction catalyst 12 are supplied to the atomic layer deposition chamber 1000. The reactant 13 and the reaction catalyst 12 may be, for example, supplied sequentially in any order or simultaneously.

The reactant 13 may be a substance that supplies a source of oxygen to the precursor 11 adsorbed on the substrate 110 and may react with the precursor 11 and/or become adsorbed on the precursor 11. The reactant 13 may include, for example, H₂O, H₂O₂, O₂, O₃, or a combination thereof.

The reaction catalyst 12 may include a primary or secondary amine catalyst and may be the same as or different from the reaction catalyst 12 used in the previous step of supplying the metal or semi-metal precursor. The primary amine catalyst may be represented by R¹NH₂ and the secondary amine catalyst may be represented by R²R³NH, wherein R¹ to R³ may each independently be a C1 to C20 alkyl group. For example, R¹ to R³ may be a short chain alkyl group, for example a C1 to C5 alkyl group. For example, the primary amine catalyst may be a C1 to C5 monoalkylamine catalyst and the secondary amine catalyst may be a C1 to C5 dialkylamine catalyst. For example, the primary amine catalyst may be methylamine, ethylamine, propylamine and/or butylamine, the secondary amine catalyst may be dimethylamine, diethylamine, methylethylamine, dipropylamine, methylpropylamine, ethylpropylamine, dibutylamine, methylbutylamine, butylethylamine, and/or butylpropylamine, but are not limited thereto. For example, the reaction catalyst 12 may include ethylamine.

The primary or secondary amine catalyst may effectively activate the precursor 11 adsorbed on the substrate 110 at relatively low temperatures as described above, thereby inducing a reaction with the reactant 13 and chemisorbed precursor on the surface of the substrate, and resulting a reaction of the reactant 13 with the chemisorbed precursor 11 at a relatively high rate. In addition, the primary or secondary amine catalyst may increase the chemical bonding between precursor 11 and reactant 13 even at relatively low temperatures, thereby increasing an atomic ratio of oxygen to metal or semi-metal, and thus, obtaining a high-quality oxide layer.

The reactant 13 adsorbed on the precursor 11 may form a layer in the form of a monolayer.

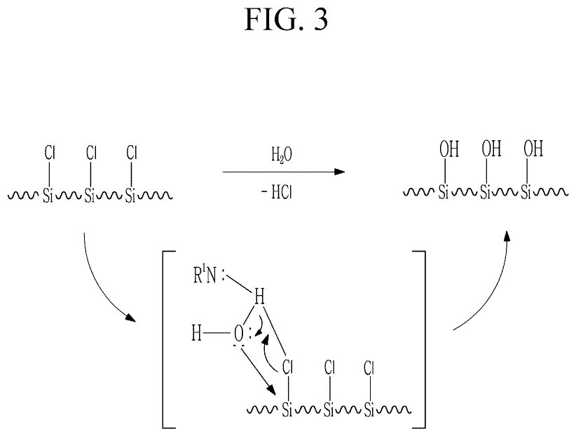

FIG. 3 is a schematic representation showing a proposed adsorption mechanism of a reactant in the atomic layer deposition. Referring to FIG. 3, when H₂O is supplied as the reactant 13 and a primary amine (R¹NH₂) catalyst is supplied as the reaction catalyst 12 to the Si—Cl bond adsorbed on the surface of the substrate 110 by the aforementioned process, the reactant 13 may be adsorbed to the surface of the substrate 110 at a high rate by increasing the reactivity. The increase in reactivity may arise from a combined effect of a coordination bond between the primary amine catalyst and the Si—Cl bond and/or a hydrogen bond between the primary amine catalyst and H₂O.

The primary or secondary amine catalyst may further increase the reaction rate of the adsorbed precursor 11 with reactant 13 as compared to tertiary amine catalysts or nitrogen-containing ring catalysts such as pyridine and pyrimidine. Moreover, a primary or secondary amine catalyst may more easily decompose after the reaction, thereby effectively reducing or eliminating catalyst residues (e.g., ammonium salts and/or carbon impurities). Accordingly, the reactant 13 may be effectively adsorbed and react the precursor 11 on a surface of the substrate 110, thus reducing catalyst residue, which in turn, may minimize or preclude chemical and electrical deterioration of the thin film.

A second purging may be performed by supplying a purge gas into the chamber 1000. The purge gas may include, for example, N₂, Ne, Ar, He, or a mixture thereof, and may be supplied at a flow rate of, for example, about 10 sccm to about 2000 sccm. The second purging may remove impurities within the atomic layer deposition chamber 1000 by discharging the aforementioned unreacted substances and/or reaction byproducts through the outlet 1220.

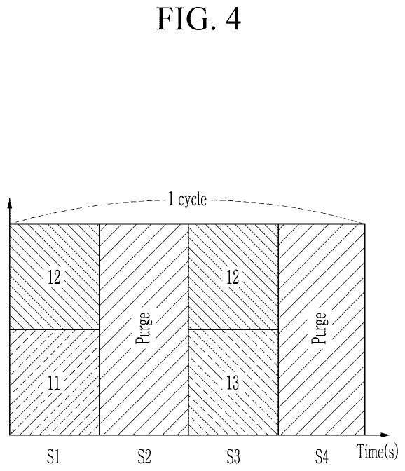

FIG. 4 is a time schematic in accordance with an embodiment showing one cycle of an atomic layer deposition. Referring to FIG. 4, the atomic layer deposition may form a layer, e.g., a monolayer, by performing a cycle of a step of supplying a metal or semi-metal precursor 11 and a first catalyst 12 (S1), a first purging step (S2), a step of supplying the reactant 13 and a second catalyst 12 (S3), and a second purging step (S4). The layer, e.g., an oxide layer, may be formed with a desired thickness by performing one or more cycles of atomic layer deposition as shown in FIG. 4. For example, the cycle shown in FIG. 4 may be performed 1 to 3000 times, but is not limited thereto.

In accordance with an embodiment, after performing one or more cycles of atomic layer deposition, an additional ozone treatment (O₃ treatment) may be performed to the formed layer. The ozone treatment may effectively remove unbound impurities proximate to or on the formed surface of the layer as well as defects or vacancies within the oxide layer and at the interface of the oxide layer, thereby obtaining a high-quality oxide layer with an improved atomic ratio of oxygen to metal or semi-metal. The ozone treatment may be conducted one or more times during the oxide layer formation process. For example, a first ozone treatment may be conducted following 5, 10, or 15 cycles shown in FIG. 4. Thereafter, a second ozone treatment may be conducted following another 5, 10, or 15 cycles, and this cycle repeated until the desired final layer formation.

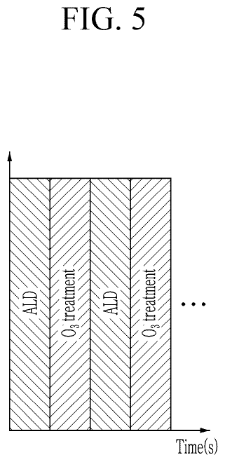

FIG. 5 is a time schematic showing an example of the sequence of the atomic layer deposition process and ozone treatment according to an embodiment in an atomic layer deposition. Referring to FIG. 5, the oxide layer may be formed by a step of conducting the aforementioned atomic layer deposition once or multiple times in cycles to form an oxide layer with a predetermined thickness (ALD), a step of conducting ozone treatment on the oxide layer (O₃ treatment), a step of conducting the aforementioned atomic layer deposition once or multiple times in cycles to form an oxide layer with a predetermined thickness on the ozone-treated oxide layer (ALD), and a step of conducting ozone treatment on the oxide layer (O₃ treatment). The oxide layer with a desired thickness may be formed by repeating n times the step of performing the atomic layer deposition to form an oxide layer with a predetermined thickness (ALD) and the step of conducting ozone treatment (O₃ treatment) on the oxide layer.

For example, the step of forming an oxide layer with a thickness of about 0.1 nm to about 30 nm by conducting atomic layer deposition 1 to 300 cycles and the step of conducting ozone treatment on the oxide layer may be alternately repeated two or more times, for example, the number of the repetition may be 2 to 300 times.

An annealing may be additionally conducted after the atomic layer deposition. The annealing may be conducted at a temperature of about 650° C. or less or about 600° C. or less, for example, at a temperature of about 150° C. to about 650° C. or about 150° C. to about 600° C.

By the process described above, an oxide layer may be formed at a high rate at a relatively low temperature of less than about 400° C. In addition, the oxide layer obtained by the aforementioned process, despite being formed at a relatively low temperature, may have a high oxygen binding ratio to the metal or semi-metal and less catalyst residue at a level equivalent to that of an oxide layer deposited at a significantly higher temperature (e.g., 600° C. or higher), thereby enabling high-quality thin film performance to be realized. In addition, an oxide layer with a thickness of angstroms to several nanometers may be formed in plural to form a thin and uniform oxide layer with a desired thickness.

In accordance with an embodied oxide layer, the carbon impurity content in the oxide layer may be less than about 2.0 at %, and within the range of 0 (no detectable carbon) to about 1.9 at %, 0 to about 1.8 at %, or 0 to about 1.7 at %. For example, the carbon impurity content in the oxide layer may be present to less than 1.2 at %, less than 1 at %, less than 0.8 at %, less than 0.6 at %, or less than 0.4 at %,

In accordance with an embodiment, the oxide layer may be a silicon oxide layer. The silicon oxide layer obtained by the above-described process may have a relatively high atomic ratio of oxygen to silicon, for example, the atomic ratio of oxygen to silicon in the silicon oxide layer may be about 1.45:1 or higher. The atomic ratio of oxygen to silicon in the silicon oxide layer may be about 2.0:1 or less. The atomic ratio of oxygen to silicon in the silicon oxide layer may be within a above range of about 1.45:1 to about 2.00:1, about 1.45:1 to about 1.90:1, or about 1.45:1 to about 1.80:1.

The aforementioned oxide layer may be applied as a dielectric layer, an insulating layer, a passivation layer and/or a protective layer in various electronic devices. The electronic device may be, for example, a semiconductor device or a display device.

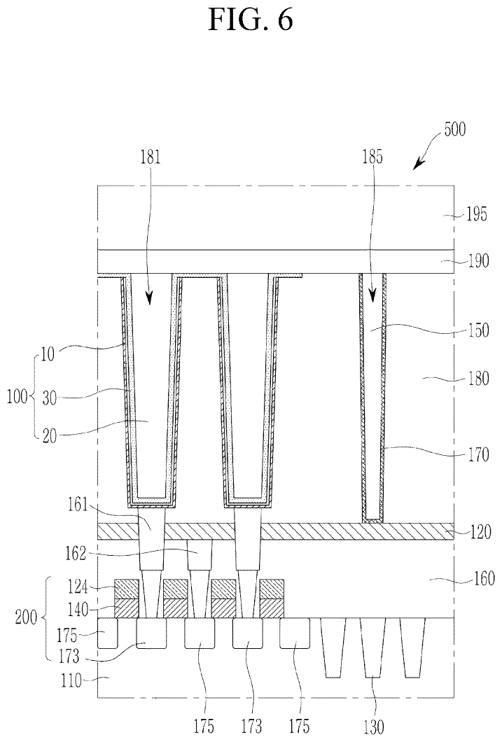

Hereinafter, an example of a semiconductor device according to an embodiment will be described. FIG. 6 is a cross-sectional view showing an example of a semiconductor device according to an embodiment. Referring to FIG. 6, a semiconductor device 500 according to one embodiment includes a semiconductor substrate 110, a transistor 200, and a capacitor 100. At least one of the transistor 200 or the capacitor 100 may include an oxide layer, and the oxide layer may be formed by the process described above. The oxide layer may be, for example, a silicon oxide layer.

The semiconductor substrate 110 may include silicon; germanium; silicon-germanium; a Group III-V compound such as GaP, GaAs, GaSb; or a combination thereof. For example, the semiconductor substrate 110 may be a silicon-on-insulator (SOI) substrate or a germanium-on-insulator (GOI) substrate.

The transistor 200 may be positioned in an active area defined by a shallow trench isolation (STI) 130 within a semiconductor substrate 110 and may be electrically connected to a bit line 120 and a capacitor 100 to perform a switching function. The transistor 200 may be a field effect transistor (FET) including a source region 173, a drain region 175, a gate electrode 124, and a gate insulating layer 140. The field-effect transistor (FET) may have various structures, including FinFETs, GAAFETs, MBCFETs, CFETs, or VFETs, but is not limited thereto.

The source region 173 and the drain region 175 are provided on a semiconductor substrate 110 and are spaced apart from each other along the in-plane direction of the semiconductor substrate 110. The source region 173 and the drain region 175 may be conductive regions doped with p-type or n-type impurities at a high concentration on the semiconductor substrate 110. In the case of an n-type transistor, the source region 173 and the drain region 175 may be doped with n-type impurities at a high concentration, and in the case of a p-type transistor, the source region 173 and the drain region 175 may be doped with p-type impurities at a high concentration. The source region 173 may be electrically connected to the capacitor 100 and the drain region 175 may be electrically connected to the bit line 120.

The gate electrode 124 is formed on a semiconductor substrate 110 and may be positioned between the source region 173 and the drain region 175. The gate electrode 124 may include a low resistance conductor, such as Ti, TiN, TiON, or a combination thereof, but are not limited thereto. The gate electrode 124 may be formed in one layer or two or more layers.

The gate insulating layer 140 may be positioned between the gate electrode 124 and the semiconductor substrate 110 and may include the aforementioned oxide layer. The gate insulating layer 140 may include an oxide layer formed by the aforementioned atomic layer deposition, and may be, for example, a silicon oxide layer. A specific description of the silicon oxide layer is as described above.

Interlayer insulating layers 160 and 180 are formed on the transistor 200. The interlayer insulating layers 160 and 180 may include an oxide, a nitride, an oxynitride, or a combination thereof, including, for example, silicon, aluminum, hafnium, lanthanum, zirconium, tantalum, yttrium, titanium, barium, strontium, or an alloy thereof, but are not limited thereto. The interlayer insulating layers 160 and 180 has a plurality of contact holes, and the contact holes are filled with a conductor to form a plurality of contacts 161, 162, and 150.

Bit lines 120 are formed between the interlayer insulating layers 160 and 180. The bit lines 120 are electrically connected to the drain region 175 of the transistor 100 through the contact 162. The bit lines 120 are arranged to cross the word lines (not shown), and a plurality of arrays may be formed by the bit lines 120 and the word lines. The word line may be electrically connected to the gate electrode 124.

The capacitor 100 is buried within the interlayer insulating layer 180, and is specifically formed within a trench 181 formed in the interlayer insulating layer 180. The shape of the trench 181 is not particularly limited, and for example, the connecting portion of the bottom and sides of the trench 181 may be round, or the sides of the trench 181 may be inclined at a predetermined angle. The trench 181 may have a high aspect ratio, and the higher the aspect ratio, the higher the capacitance of the capacitor 100. The capacitor 100 is electrically connected to the source region 173 of the transistor 100 through a contact 161.

A capacitor 100 includes a first electrode 10, a dielectric layer 30, and a second electrode 20.

The first electrode 10 is positioned along the inner wall of the interlayer insulating layer 180 within the trench 181. The first electrode 10 may be a thin film, for example, a continuous thin film formed with a substantially uniform thickness along the inner wall of the interlayer insulating layer 180 within the trench 181. For example, the first electrode 10 may be formed by atomic layer deposition (ALD).

The dielectric layer 30 may include an oxide layer formed by the aforementioned atomic layer deposition, and may be, for example, a silicon oxide layer. A specific description of the silicon oxide layer is as described above. The dielectric layer 30 is positioned on the first electrode 10 along the inner wall of the interlayer insulating layer 180 within the trench 181 and may be, for example, a continuous thin film formed with a substantially uniform thickness along the inner wall of the interlayer insulating layer 180 within the trench 181. A thickness of the dielectric layer 30 may be about 1 nm to about 100 nm, and within the above range may be about 2 nm to about 80 nm, about 2 nm to about 50 nm, or about 2 nm to about 30 nm.

The second electrode 20 may fill the interior of the trench 181. However, it is not limited thereto, and the second electrode 20 may fill a part of the trench 181 and be filled with a filler thereon. The second electrode 20 may include, for example, a metal, a metal nitride, a metal oxynitride or a combination thereof, and may include, for example, Ti, TiN, TiON, TaN, MoN, CoN, TiAlN, TaAlN, W, Ru, Ir, IrO₂, Pt or a combination thereof, but is not limited thereto.

The contact 150 may be located within the interlayer insulating layer 180, and the bit line 120 and the upper wire may be electrically connected through the contact 150. A barrier layer 170 may be formed around the contact 150.

On top of the capacitor 100, one or more layers of interlayer insulating layers 190 and 195 are positioned, and the capacitor 100 may be electrically connected to wire (not shown) buried in the interlayer insulating layers 190 and 195.

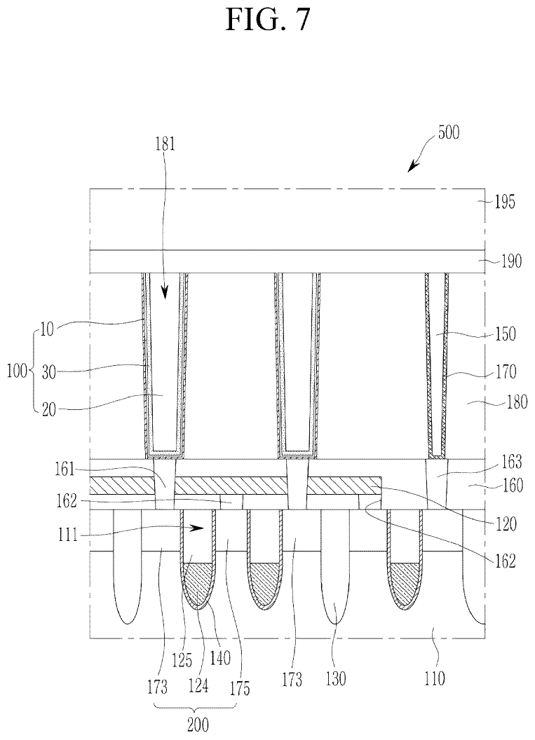

FIG. 7 is a cross-sectional view showing another example of a semiconductor device according to an embodiment. Referring to FIG. 7, a semiconductor device 500 according to an embodiment includes a semiconductor substrate 110, a transistor 200, and a capacitor 100, similar to the example described above. At least one of the transistor 200 or the capacitor 100 may include an oxide layer, and the oxide layer may be formed by the method described above. The oxide layer may be, for example, a silicon oxide layer.

However, the semiconductor device 500 according to the present example may include a transistor 200 having a BCAT (buried cell array transistor) structure in which a gate electrode 124 and a gate insulating layer 140 are buried within a semiconductor substrate 110.

Specifically, the transistor 200 has a plurality of trenches 111. The trenches 111 are formed at a predetermined depth from the surface of the semiconductor substrate 110 and may expose the inner wall of the semiconductor substrate 110. The shapes of the trenches 111 are not particularly limited, and for example, the connecting portion of the bottom surface and the sides surface of the trenches 111 may have a round shape, or the sides surface of the trenches 111 may have a shape inclined at a predetermined angle.

The gate insulating layer 140 is positioned along the inner wall of the semiconductor substrate 110 within the trench 111. The gate insulating layer 140 may include the aforementioned oxide layer, and may be, for example, a silicon oxide layer. The gate insulating layer 140 may be a continuous thin film formed with a substantially uniform thickness along the inner wall of the semiconductor substrate 110 within the trench 111, for example, by the aforementioned atomic layer deposition method. A thickness of the gate insulating layer 140 may be, for example, about 1 nm to about 30 nm, and within the above range, about 3 nm to about 20 nm or about 5 nm to about 10 nm.

The gate electrode 124 may fill a portion of the trench 111. However, it is not limited thereto, and the gate electrode 124 may be a continuous thin film positioned on the gate insulating layer 140 along the inner wall of the semiconductor substrate 110 within the trench 111. The gate electrode 124 may include a low resistance conductor such as Ti, TiN, TiON, or a combination thereof. A thickness of the gate electrode 124 may be, for example, about 1 nm to about 30 nm, and within the above range, about 3 nm to about 20 nm or about 5 nm to about 10 nm.

A filling conductive layer 125 is formed on the gate electrode 124. The filling conductive layer 125 fills the trench 111 and may be electrically connected to a word line (not shown). The filling conductive layer 125 may include Ti, TiN, TiON, tungsten, or a combination thereof, but is not limited thereto.

A DRAM device has been described as an example of a semiconductor device, but is not limited thereto, and may be applied to all semiconductor devices including oxide layers. For example, the semiconductor device may be used for arithmetic operation, program execution, and/or temporary data retention, etc.

The semiconductor device may be included in various electronic devices. The electronic devices may include, for example, mobile devices, computers, laptops, tablet PC, smart watches, sensors, digital cameras, electronic books, network devices, car navigators, Internet of Things (IoT), Internet of Everything (IoE), drones, door locks, safes, automated teller machines (ATM), security devices, medical devices, automobile electrical components, or etc. but are not limited thereto.

For example, the electronic device may include a memory unit, an arithmetic logic unit, and a control unit, which may be electrically connected. For example, a memory unit, an arithmetic logic unit, and a control unit may be implemented in a chip, and for example, may be implemented in a chip by monolithically integrating them on a substrate. The memory unit, the arithmetic logic unit and the control unit may each independently include the capacitors and/or semiconductor devices described above. An electronic device may be connected to one or more input/output devices.

Hereinafter, the embodiments are illustrated in more detail with reference to examples. However, these examples are exemplary, and the present scope is not limited thereto.

### Formation of Silicon Oxide Layer

### Preparation Example 1

A silicon substrate is immersed in an SC-1 solution (NH₄OH:H₂O₂:DIW=volume ratio of 1:1:5) and heat-treated at a temperature of 70 to 80° C. for 10 minutes. The substrate is then rinsed with deionized water (DIW) for 3 minutes to prepare a silicon substrate surface-treated with hydroxyl groups. The silicon substrate surface-treated with hydroxyl groups is placed in a chamber (100° C., 1 Torr or less) of a traveling-wave typed atomic layer deposition equipment. Hexachlorodisilane (HCDS) and an ethylamine catalyst are simultaneously injected into the chamber for 5 seconds. Supply pressures of the hexachlorodisilane and the ethylamine catalyst are maintained at 0.3 to 0.4 torr and 0.6 to 0.7 torr, respectively. Subsequently, nitrogen gas (N₂, 99.999%) is supplied into the chamber at a flow rate of 300 standard cubic centimeters per minute (sccm) for 30 seconds to provide a first purge of the chamber. Water (DIW) and the ethylamine catalyst are simultaneously injected into the chamber for 8 seconds. Supply pressures of the water and the ethylamine catalyst are maintained at 0.7 to 0.8 torr and 0.6 to 0.7 torr, respectively. Nitrogen gas (N₂, 99.999%) is supplied into the chamber at a flow rate of 300 sccm for 60 seconds to provide a second purge. The above process is performed as 1 cycle to form a silicon oxide layer with a thickness of 1.14 Å/cycle. The above one-cycle process is repeated for a total of 176 cycles to form a silicon oxide layer with a total thickness of about 20 nm.

### Preparation Example 2

A silicon substrate is immersed in an SC-1 solution (NH₄OH:H₂O₂:DIW=volume ratio of 1:1:5) and heat-treated at a temperature of 70 to 80° C. for 10 minutes. The substrate is then rinsed with deionized water (DIW) for 3 minutes to prepare a silicon substrate surface-treated with hydroxyl groups. The silicon substrate surface-treated with hydroxyl groups is placed in a chamber (100° C., 1 Torr or less) of a traveling-wave typed atomic layer deposition equipment. Hexachlorodisilane (HCDS) and an ethylamine catalyst are simultaneously injected into the chamber for 5 seconds. Supply pressures of the hexachlorodisilane and the ethylamine catalyst are maintained at 0.3 to 0.4 torr and 0.6 to 0.7 torr, respectively. Subsequently, nitrogen gas (N₂, 99.999%) is supplied into the chamber at a flow rate of 300 sccm for 30 seconds to provide a first purge of the chamber. Water (DIW) and the ethylamine catalyst are simultaneously injected into the chamber for 8 seconds. Supply pressures of the water and the ethylamine catalyst are maintained at 0.7 to 0.8 torr and 0.6 to 0.7 torr, respectively. Nitrogen gas (N₂, 99.999%) is supplied into the chamber at a flow rate of 300 sccm for 60 seconds to provide a second purge. The above process is performed as 1 cycle to form a silicon oxide layer with a thickness of 1.14 Å/cycle. The above one-cycle process is repeated a total of 35 cycles to form a silicon oxide layer with a thickness of about 4 nm. An ozone treatment (180 g/m³) of the silicon oxide layer is then conducted. A repeated sequence of 35 cycles of silicon oxide formation is followed by an ozone treatment of the resulting silicon oxide layer and this sequence is repeated for a total of 5 times to form a silicon oxide layer with a total thickness of about 20 nm.

### Comparative Preparation Example 1

A silicon substrate is immersed in an SC-1 solution (NH₄OH:H₂O₂:DIW=volume ratio of 1:1:5) and heat-treated at a temperature of 70 to 80° C. for 10 minutes. The substrate is rinsed with deionized water (DIW) for 3 minutes to prepare a silicon substrate surface-treated with hydroxyl groups. The silicon substrate surface-treated with hydroxyl groups is placed in a chamber (100° C., 1 Torr or less) of traveling-wave typed atomic layer deposition equipment. Hexachlorodisilane (HCDS) and a pyridine catalyst are simultaneously injected into the chamber for 5 seconds. Supply pressures of the hexachlorodisilane and the pyridine catalyst are maintained at 0.3 to 0.4 torr and 0.6 to 0.7 torr, respectively. Nitrogen gas (N₂, 99.999%) is supplied into the chamber at a flow rate of 300 sccm for 30 seconds for first purging. Water (DIW) and the pyridine catalyst are simultaneously injected into the chamber for 8 seconds. Supply pressures of the water and the pyridine catalyst are maintained at 0.7 to 0.8 torr and 0.6 to 0.7 torr, respectively. Nitrogen gas (N₂, 99.999%) is supplied to the chamber at a flow rate of 300 sccm for 60 seconds for second purging. The above process is performed as 1 cycle to form a silicon oxide layer with a thickness of 1.03 Å/cycle. The above process is repeated for a total of 195 cycles to form a silicon oxide layer with a total thickness of about 20 nm.

### Comparative Preparation Example 2

A silicon substrate is immersed in an SC-1 solution (NH₄OH:H₂O₂:DIW=1:1:5 in a volume ratio) and heat-treated at a temperature of 70 to 80° C. for 10 minutes. The substrate is rinsed with deionized water (DIW) for 3 minutes to prepare a silicon substrate surface-treated with hydroxyl groups. The silicon substrate surface-treated with hydroxyl groups is placed in a chamber (100° C., 1 Torr or less) of a traveling-wave typed atomic layer deposition equipment. Hexachlorodisilane (HCDS) and a pyridine catalyst are simultaneously injected into the chamber for 5 seconds. Supply pressures of the hexachlorodisilane and the pyridine catalyst are maintained at 0.3 to 0.4 torr and 0.6 to 0.7 torr, respectively. Nitrogen gas (N₂, 99.999%) is supplied into the chamber at a flow rate of 300 sccm for 30 seconds for first purging. Water (DIW) and the pyridine catalyst are simultaneously injected thereinto for 8 seconds. Supply pressures of the water and the pyridine catalyst are maintained at 0.7 to 0.8 torr and 0.6 to 0.7 torr, respectively. Nitrogen gas (N₂, 99.999%) is supplied to the chamber at a flow rate of 300 sccm for 60 seconds for second purging. The above process is performed as 1 cycle to form a silicon oxide layer with a thickness of 1.03 Å/cycle. The above process is repeated for a total of 39 cycles to form a silicon oxide layer with a thickness of about 4 nm. The silicon oxide layer is then subjected to an ozone-treatment (180 g/m³). A repeated sequence of 39 cycles of silicon oxide formation is followed by an ozone treatment of the resulting silicon oxide layer and this sequence is repeated for a total of 5 times repeated to form a silicon oxide layer with a total thickness of about 20 nm.

### Comparative Preparation Example 3

A silicon oxide layer is formed in the same manner as in Preparation Example 1 except that a triethylamine catalyst is used instead of the ethylamine catalyst.

### Comparative Preparation Example 4

A silicon oxide layer is formed in the same manner as in Preparation Example 2 except that a triethylamine catalyst is used instead of the ethylamine catalyst.

### Reference Preparation Example—Deposition Temperature of 600° C.

A silicon substrate is immersed in an SC-1 solution (NH₄OH:H₂O₂:DIW=volume ratio of 1:1:5) and heat-treated at a temperature of 70 to 80° C. for 10 minutes. The substrate is rinsed with deionized water (DIW) for 3 minutes to prepare a silicon substrate surface-treated with hydroxyl groups. The silicon substrate surface-treated with hydroxyl groups is placed in a chamber (600° C., 1 Torr or less) of a traveling-wave typed atomic layer deposition equipment. Hexachlorodisilane (HCDS) and an ethylamine catalyst are simultaneously injected into the chamber for 5 seconds. A supply pressure of the hexachlorodisilane (HCDS) and the ethylamine catalyst is maintained at 0.3 to 0.4 torr, and 0.6 to 0.7 torr, respectively. Nitrogen gas (N₂, 99.999%) is supplied into the chamber at a flow rate of 300 sccm for 30 seconds for first purging. Hydrogen peroxide (H₂O₂) is injected into the chamber for 7 seconds. A supply pressure of the hydrogen peroxide is maintained at 0.7 to 0.8 torr. Nitrogen gas (N₂, 99.999%) is supplied into the chamber at a flow rate of 300 sccm for 45 seconds for second purging. The above process is performed as 1 cycle to form a silicon oxide layer with a thickness of 1.51 Å/cycle. The above process is repeated for a total of 392 cycles to form a silicon oxide layer with a total thickness of about 20 nm.

### Evaluation I

The silicon oxide layers of the Preparation Examples and the Comparative Preparation Examples are evaluated with respect to their respective film characteristics, properties, and elemental compositions.

For example, each of the silicon oxide layers is evaluated with respect to elemental compositions and chemical bonding structures by X-ray photoelectron spectroscopy (XPS). In addition, each of the silicon oxide layers is evaluated with in an attenuated total internal reflection (ATR) mode of infrared spectroscopy to access the Si—O bonding.

The elemental results are shown in Tables 1 and 2.

TABLE 1
Elemental Composition (atomic percent)

| | Si | O | Cl | C | N |
|---|---|---|---|---|---|
| Reference Preparation Example | 38.3 | 61.7 | 0 | 0 | 0 |
| Preparation Example 1 | 39 | 57.7 | 0.6 | 1.6 | 1.1 |
| Comparative Preparation Example 1 | 39.8 | 56.2 | 0.7 | 2.2 | 1.1 |
| Preparation Example 2 | 38.6 | 61.4 | 0 | 0 | 0 |
| Comparative Preparation Example 2 | 41 | 59 | 0 | 0 | 0 |

TABLE 2
O:Si atomic ratio

| | O:Si ratio |
|---|---|
| Reference Preparation Example | 1.61:1 |
| Preparation Example 1 | 1.48:1 |
| Comparative Preparation Example 1 | 1.41:1 |
| Preparation Example 2 | 1.59:1 |
| Comparative Preparation Example 2 | 1.44:1 |

Referring to Table 1, it may be confirmed that the silicon oxide layer of Preparation Example 1 has a reduced content of carbon impurities compared to the silicon oxide layer of Comparative Preparation Example 1. In addition, it may be confirmed that carbon impurities in the silicon oxide layer of Preparation Example 2 are completely removed by the repeated intermittent ozone treatments during the making of the silicon oxide layer.

Referring to Table 2, it may be confirmed that the silicon oxide layer of Preparation Example 1 exhibits a high ratio of oxygen to silicon compared to the silicon oxide layer of Comparative Preparation Example 1. Likewise, it may be confirmed that the silicon oxide layer of Preparation Example 2 exhibits a high ratio of oxygen to silicon compared to the silicon oxide layer of Comparative Preparation Example 2. In addition, it may be confirmed that the silicon oxide layer of Preparation Example 2 has an O:Si atomic ratio that is near equivalent to the O:Si atomic ratio of the silicon oxide layer of Reference Preparation Example in which the atomic layer deposition is performed at a high temperature of 600° C.

Accordingly, it may be confirmed that the silicon oxide layers of Preparation Examples are formed as a high-quality thin film with a high oxygen content, even though the layers are formed by atomic layer deposition at a significantly lower temperature.

### Evaluation II

The silicon oxide layers of Reference Preparation Example, Preparation Example 2, and Comparative Preparation Example 2 are evaluated with respect to chemical stability after annealing each of the layers at 600° C. The chemical stability of the silicon oxide layers is evaluated by measuring a thickness reduction by etching after immersing the layers in a 0.1% diluted hydrofluoric acid (HF) and rinsing with distilled water.

The results are shown in Table 3.

TABLE 3

| | Etch Rate |
|---|---|
| | (Å/sec @ 600° C.) |
| Reference Preparation Example | 1.26 |
| Preparation Example 2 | 0.40 |
| Comparative Preparation Example 2 | 0.52 |

Referring to Table 3, it may be confirmed that the silicon oxide layer of Preparation Example 2 exhibits a low etch rate, and accordingly, has higher chemical stability due to high film density, compared to the silicon oxide layers of Reference Preparation Example and Comparative Preparation Example 2.

### Manufacturing of Semiconductor Devices

### Example 1

A silicon oxide layer is formed on a boron-doped p-type Si (100) substrate in the atomic layer deposition process described in Preparation Example 1. The silicon oxide layer is annealed at 600° C. for 30 seconds under a nitrogen atmosphere. Then, a 100 nm-thick titanium nitride (TiN) layer is formed on the silicon oxide layer by sputtering and then, annealed at 400° C. for 10 minutes under an atmosphere of 5% H₂/N₂ to form a gate electrode. Thereafter, a liquid indium-gallium eutectic alloy is used to form an ohmic contact to provide a semiconductor device (i.e., a MOS capacitor).

### Example 2

A semiconductor device (MOS capacitor) is manufactured in the same manner as in Example 1 except that a silicon oxide layer is formed in the atomic layer deposition process described in Preparation Example 2 instead of the atomic layer deposition process described in Preparation Example 1.

### Comparative Example 1

A semiconductor device (MOS capacitor) is manufactured in the same manner as in Example 1 except that a silicon oxide layer is formed in the atomic layer deposition process described in Comparative Preparation Example 1 instead of the atomic layer deposition process described in Preparation Example 1.

### Comparative Example 2

A semiconductor device (MOS capacitor) is manufactured in the same manner as in Example 1 except that a silicon oxide layer is formed in the atomic layer deposition process described in Comparative Preparation Example 2 instead of the atomic layer deposition process described in Preparation Example 1.

### Comparative Example 3

A semiconductor device (MOS capacitor) is manufactured in the same manner as in Example 1 except that a silicon oxide layer is formed in the atomic layer deposition process described in Comparative Preparation Example 3 instead of the atomic layer deposition process described in Preparation Example 1.

### Comparative Example 4

A semiconductor device (MOS capacitor) is manufactured in the same manner as in Example 1 except that a silicon oxide layer is formed in the atomic layer deposition process described in Comparative Preparation Example 4 instead of the atomic layer deposition process described in Preparation Example 1.

### Reference Example

A semiconductor device (MOS capacitor) is manufactured in the same manner as in Example 1 except that a silicon oxide layer is formed in the atomic layer deposition process described in Reference Preparation Example instead of the atomic layer deposition process described in Preparation Example 1.

### Evaluation III

The semiconductor devices (MOS capacitor) of the Reference Example, Examples 1 and 2, and Comparative Examples 1 to 4 are evaluated with respect to electrical characteristics. The electrical characteristics of the semiconductor devices (MOS capacitor) are evaluated by measuring C-V (capacitance-voltage) and Jg-V (leakage current density-voltage) with a semiconductor parameter analyzer system. The results are shown in Table 4.

TABLE 4

| | Permittivity | Hysteresis | V_{b} |
|---|---|---|---|
| | (K) | (mV) | (mV/cm) |
| Reference Example | 3.7 | 52 | 10 |
| Example 1 | 3.96 | 10 | 9.7 |
| Comparative Example 1 | 3.5 | 120 | 9.2 |
| Comparative Example 3 | 3.91 | 76 | 9.1 |
| Example 2 | 4.05 | 18 | 9.8 |
| Comparative Example 2 | 3.92 | 21 | 9.9 |
| Comparative Example 4 | 3.97 | 26 | 9.6 |

* V_{b}: breakdown voltage

Referring to Table 4, it may be confirmed that the semiconductor device of Example 1 exhibits improved electrical characteristics compared to the semiconductor devices of Comparative Examples 1 and 3. Likewise, it may be confirmed that the semiconductor device of Example 2 exhibits improved electrical characteristics compared to the semiconductor devices of Comparative Exampled 2 and 4. Furthermore, it may be confirmed that the semiconductor devices of Examples 1 and 2 exhibit equivalent or improved electrical characteristics, compared with the semiconductor device of Reference Example in which the atomic layer deposition process is performed at a significantly higher temperature of 600° C.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A process of forming an oxide layer, the process comprising conducting atomic layer deposition at a temperature of less than about 400° C., wherein the atomic layer deposition comprises:
supplying a metal or semi-metal precursor and a first reaction catalyst to a substrate positioned in a chamber for atomic layer deposition to adsorb the metal or the semimetal precursor on a surface of the substrate; and
supplying a reactant and a second reaction catalyst to the substrate on which the metal or semi-metal precursor is adsorbed to form the oxide layer, and
wherein the first reaction catalyst and the second reaction catalyst comprise primary or secondary amine, respectively.

2. The process of claim 1, wherein at least one of the first reaction catalyst or the second reaction catalyst comprise a C1 to C5 monoalkylamine compound, a C1 to C5 dialkylamine compound, or a combination thereof.

3. The process of claim 1, wherein at least one of the first reaction catalyst or the second reaction catalyst comprise ethylamine.

4. The process of claim 1, wherein
the metal or semi-metal precursor comprises a halosilane, a halodisilane, an alkoxysilane, an alkoxydisilane, an organosilane, an organodisilane, a metal halide, a metal alkoxide, an organometallic precursor, or a combination thereof, and
the reactant comprises H₂O, H₂O₂, O₂, O₃, or a combination thereof.

5. The process of claim 1, further comprising
supplying a first purge gas following the adsorbing of the metal or semi-metal precursor to the substrate surface, and before the supplying the reactant and the second reaction catalyst; and
supplying a second purge gas after the supplying the reactant and the second reaction catalyst to the substrate.

6. The process of claim 1, wherein the atomic layer deposition is conducted at about room temperature to less than or equal to about 150° C.

7. The process of claim 1, further comprising conducting an ozone treatment of an intermediate oxide layer following a two or more of atomic deposition cycles, wherein one atomic deposition cycle includes the supplying the metal or semi-metal precursor and the first catalyst, and the supplying the reactant and the second reaction catalyst.

8. The process of claim 1, wherein
one atomic layer deposition cycle includes the supplying the metal or semi-metal precursor and the first reaction catalyst, and the supplying the reactant and the second reaction catalyst,
wherein a number of 2 to 300 atomic layer deposition cycles is conducted to form an intermediate oxide layer, and
conducting an ozone treatment on the intermediate oxide layer following the number of atomic layer deposition cycles, wherein the ozone treatment is conducted two or more times over a total number of atomic layer deposition cycles.

9. The process of claim 1, further comprising annealing the oxide layer.

10. The process of claim 1, wherein a carbon content in the oxide layer is less than about 2.0 atomic percent.

11. The process of claim 1, wherein
the oxide layer is a silicon oxide layer, and
an atomic ratio of oxygen to silicon in the silicon oxide layer is about 1.45:1 to about 2.00:1.

12. An oxide layer formed by the process of claim 1, the oxide layer having a carbon content of less than about 2.0 atomic percent.

13. The oxide layer of claim 12, wherein
the oxide layer is a silicon oxide layer, and
an atomic ratio of oxygen to silicon in the silicon oxide layer is about 1.45:1 to about 2.00:1.

14. A semiconductor device comprising
a semiconductor substrate,
a transistor integrated into or positioned on the semiconductor substrate, and
a capacitor electrically connected to the transistor,
wherein at least one of the transistor or the capacitor comprises the oxide layer of claim 12.

15. A method of manufacturing a semiconductor device, the method comprising:
forming a transistor integrated into or positioned on a semiconductor substrate; and
forming a capacitor electrically connected to the transistor;
wherein at least one of the forming the transistor or the forming the capacitor comprises forming an oxide layer by the process of claim 1.

16. The method of claim 15, wherein a carbon content of the oxide layer is less than about 2.0 atomic percent.

17. The method of claim 15, wherein
the oxide layer is a silicon oxide layer, and
an atomic ratio of oxygen to silicon of the silicon oxide layer is about 1.45:1 to about 2.00:1.

18. The method of claim 15, wherein the forming of the capacitor comprises
forming a first electrode,
forming the oxide layer, and
forming a second electrode.

19. The method of claim 15, wherein the forming of the transistor comprises
forming a trench in the semiconductor substrate,
forming the oxide layer in the trench, and
forming a gate conductor on the oxide layer.

20. The method of claim 19, wherein the oxide layer is formed as a continuous thin film having a substantially uniform thickness along an inner wall of the trench of the semiconductor substrate.
